(19) United States
(12) Patent Application Publication
(10) Pub. No.: US 2005/0035444 A1
(43) Pub. Date: Feb. 17, 2005

(54) Multi-chip package device with heat sink and fabrication method thereof

(75) Inventor: Chien-Ping Huang, Taichung (TW)

Correspondence Address: Mr. Steven M. Jensen;Mr. Peter F. Corless, EDWARDS & ANGELL, LLP, 101 Federal Street, Boston, MA, 02110, US

(73) Assignee: SILICONWARE PRECISION INDUSTRIES

(21) Appl. No.: 10/696,198

(22) Filed: Oct. 28, 2003

(30) Foreign Application Priority Data
Aug. 11, 2003 (TW) 092121955

(51) Int. Cl. H01L 23/10

(52) U.S. Cl. 257/706

(57) ABSTRACT

A multi-chip package device with heat sink and a fabrication method thereof are proposed. At least one first chip and at least one semiconductor package are mounted on and electrically connected to a chip carrier. Then, a heat sink is mounted via an adhesion layer to the first chip and the semiconductor package. In addition, at least one hollow part extending through the heat sink is formed in an area of the heat sink free of contact from the first chip and the semiconductor package, in order to release thermal stresses produced from the heat sink. Thereby, the package device can be prevented from being damaged during the reliability test process, and a product yield is thereby promoted.

### FIELD OF THE INVENTION

The present invention relates to multi-chip package devices and fabrication methods thereof, and more particularly, to a multi-chip package device with a heat sink, which can release thermal stresses from the heat sink, and a fabrication method of the package device.

### BACKGROUND OF THE INVENTION

With a growing demand for minimized electrical products with high operation speed, a semiconductor package device is presented with a Multi Chip Module (MCM) to improve performance and capacity of a single package device and to meet requirements for the electrical product with a minimal size, maximal capacity and high operation speed. As this package device has a reduced overall size and improved electrical functions, it becomes one of the main trends among the packaged products.

For example of a graphic adapter that is installed in a Personal Computer (PC) to rapidly process and display graphics, particularly 3-dimensional (3D) graphics, besides a Graphic Processing Unit (GPU) for processing graphics, a graphic chip package further comprises a memory chip that provides higher speed of data access. This memory chip is usually a volatile Random Access Memory (RAM), such as Dynamic Random Access Memory (DRAM), Synchronous Dynamic Random Access Memory (SDRAM), or Double Data Rate SDRAM (DDRSDRAM). In such a graphic chip package device having the GPU and the memory chip, there are usually a plurality of semiconductor chips mounted side by side on a chip mounting area of a chip carrier.

FIG. 1 shows an integrated circuit package device for receiving another integrated circuit disclosed in U.S. Pat. No. 6,020,633. The integrated circuit package device 1 comprises a Printed Circuit Board (PCB) carrier 10 having two layers and three surfaces i.e. top, middle, and bottom surfaces with conductive traces used for electrically connection, and a Field Programmable Gate Array (FPGA) 11. The carrier 10 is formed with four types of conductive traces including: trace 12a for electrically connecting wire 11a to bump 13a located on a lower surface of the carrier 10; trace 12b for electrically connecting wire 11b to contact pad 14a at an upper surface of the carrier 10; trace 12c for electrically connecting wire 11c to bump 13b on the lower surface of the carrier 10 and contact pad 14b at the upper surface of the carrier 10; and trace 12d for electrically connecting contact pad 14c to bump 13c.

Moreover, in order to program the FPGA 11, a Programmable Read Only Memory (PROM) 15 is attached to the upper surface of the carrier 10 not interfering with the FPGA 11 and wires 11a, 11b and 11c. The PROM 15 has a lower cover 16 and an upper cover 17 and is electrically connected via a plurality of bumps 18 to the contact pads 14a, 14b and 14c.

Further, the above integrated circuit package device 1 is only provided with a heat sink over the FPGA for heat dissipation. As discussed above, in order to achieve rapid graphic processing, the current graphic chip package is provided with a plurality of semiconductor chips, such as microprocessor chip, memory chip, and so on. With the chip processing technology keeps advancing, both the data processing speed and the memory capacity are significantly enhanced. And the enhancement in the processing speed is usually accompanied by a large amount of heat generated when the chip executes the computation. Therefore, the conventional multi-chip package device that lacks an effective heat sink is not suitable to be packaged in the highly efficient semiconductor chip.

To resolve the heat dissipation problem associated with this type of multi-chip package device, another conventional package assembly with a heat sink is proposed and illustrated in FIG. 2. As shown, this package assembly 2 has a chip carrier 20, at least one first chip 21 and a plurality of semiconductor packages 22 mounted on the chip carrier 20, and a heat sink 24 that is attached via an adhesion layer 23 to a surface of the first chip 21 and a surface of each semiconductor package 22. The first chip 21 is mounted on the chip carrier 22 in a flip-chip manner, and the semiconductor packages 22 are mounted on the chip carrier 20 by Surface Mount Technology (SMT). As shown in FIG. 2, the semiconductor packages 22 are thicker than the first chip 21 and can be Thin and Fine-pitch Ball Grid Array (TFBGA) packages. The heat sink 24 is used to dissipate heat generated from the first chip 21 and the semiconductor packages 22, thereby desirably enhancing the heat dissipating efficiency of the package assembly 2.

However, the above package assembly 2 still encounters significant problems. Due to mismatch in Coefficient of Thermal Expansion (CTE) among the chip carrier 20, the first chip 21, the semiconductor packages 22, the adhesion layer 23, and the heat sink 24, when the package assembly 2 is subject to subsequent fabrication processes such as reliability tests with great temperature variations e.g. Thermal Cycling Test (TCT), Thermal Shock Test (TST), and High Temperature Storage-life Test (HTST), thermal stresses are produced in response to the CTE mismatch and may damage the quality of the package assembly 2. For example of the first chip 21 and the heat sink 24, copper for forming the heat sink 24 has an average CTE of about 16.3 ppm/° C., while silicon for making the first chip 21 has an average CTE ranged from about 2.8 ppm/° C. to 3.3 ppm/° C. As a result, the thermal stresses produced under a high temperature environment and rapid temperature fluctuation may lead to damage at the interface between the first chip 21 and the heat sink 24 such as delamination. Moreover, the heat sink 24 in the package assembly 2 has a plurality of portions with different thicknesses; for example, the portion of the heat sink 24 connected to the first chip 21 is thicker than the portion of the heat sink 24 attached to the semiconductor packages 22. This thickness difference would undesirably facilitate damage induced by the thermal stresses to internal structure of the package assembly 2.

Referring to FIG. 3a, when the package assembly 2 is subject to a temperature-increasing environment, the heat sink 24 having the larger CTE thermally expands to a greater extent than the first chip 21, and the heat sink 24, which is attached to both the first chip 21 and the semiconductor packages 22, would deform or bend by different thermal expansions of the portions having different thicknesses of the heat sink 24. The deformation or bending further leads to warpage for the heat sink 24, the first chip 21, and the semiconductor packages 22, and in turn causes cracking 25 of the first chip 21 and delamination of the heat sink 24 from the first chip 21 and from the semiconductor packages 22, as well as deteriorates the flip-chip bump connection between the first chip 21 or semiconductor packages 22 and the chip carrier 20. Moreover, if the semiconductor packages 22 are attached to periphery areas of the heat sink 24, a restrained boundary condition is produced and causes the heat sink 24 to buckle, making the periphery areas and corners of the heat sink 24 restrained and subject to the greatest stresses.

Referring to FIG. 3b, bending of the heat sink 24 may also occur in the case of the heat sink 24 contracting to a greater extent than the first chip 21 and the semiconductor packages 22 when the package assembly 2 is subject to a temperature-decreasing environment. This bending of the heat sink 24 similarly leads to warpage for the heat sink 24, the first chip 21, and the semiconductor packages 22. The greater contraction of the heat sink 24 may further exert a pressure on the first chip 21 and the semiconductor packages 22, leading to cracking 25 of the first chip 21.

In addition, if the foregoing thermal stresses generated under temperature variations cannot be released successfully, residual stresses leaving on the peripheral areas and corners of the heat sink 24 that are subject to the largest stresses would result in structural damage to the package assembly 2, such as cracking at the junctions between the first chip 21, the semiconductor packages 22, and the heat sink 24, thereby degrading the quality of the package assembly 2.

Therefore, in order to resolve the above-mentioned problems, it is greatly desirable to provide a multi-chip package device with a heat sink to effectively release thermal stresses and assure the quality of the package device.

### SUMMARY OF THE INVENTION

A primary objective of the present invention is to provide a multi-chip package device with a heat sink and a fabrication method thereof, to allow thermal stresses to be released from locations of the heat sink subject to the greatest stresses, so as to prevent delamination between the heat sink and a chip mounted in the package device.

Another objective of the present invention is to provide a multi-chip package device with a heat sink and a fabrication method thereof, to allow thermal stresses to be released from locations of the heat sink subject to the greatest stresses, so as to prevent a chip mounted in the package device from being pressed and damaged.

A further objective of the present invention is to provide a multi-chip package device with a heat sink and a fabrication method thereof, to allow thermal stresses to be released from locations of the heat sink subject to the greatest stresses, so as to prevent warpage for the heat sink and a chip carrier and a chip mounted in the package device.

A further objective of the present invention is to provide a multi-chip package device with a heat sink and a fabrication method thereof, to allow thermal stresses to be released from locations of the heat sink subject to the greatest stresses, so as to ensure bonding quality between a chip carrier and a chip mounted in the package device.

In accordance with the above and other objectives, the present invention proposes a multi-chip package device with a heat sink. The multi-chip package device comprises: a chip carrier for electrically connecting the semiconductor package device to an external device; at least one first chip mounted in a flip-chip manner on a chip mounting area of the chip carrier; at least one semiconductor package mounted on the chip mounting area of the chip carrier; and the heat sink mounted via an adhesion layer on a surface of the first chip and a surface of the semiconductor package that are opposite to surfaces of the first chip and the semiconductor package mounted on the chip carrier, wherein at least one hollow part extending through the heat sink is formed at an area of the heat sink free of contact with the first chip and the semiconductor package to release thermal stresses from the heat sink.

The above multi-chip package device is fabricated by preparing the chip carrier, and mounting and electrical connecting the first chip and the semiconductor package to the chip mounting area of the chip carrier. Then, the heat sink is attached via the adhesion layer to the first chip and the semiconductor package.

The primary advantage achieved by the multi-chip package device according to the present invention is that, the provision of the hollow part in the heat sink allows thermal stresses produced from the heat sink to be release from a location of the heat sink subject to the greatest stresses, so as to prevent delamination, cracking and warpage in the package device from occurrence.

### BRIEF DESCRIPTION OF THE DRAWINGS

The present invention can be more fully understood by reading the following detailed description of the preferred embodiments, with reference made to the accompanying drawings wherein:

FIG. 1 (PRIOR ART) is a schematic cross-sectional view of a conventional multi-chip package device;

FIG. 2 (PRIOR ART) is a schematic cross-sectional view of a conventional multi-chip package device with a heat sink;

FIG. 3a (PRIOR ART) is a schematic view showing the conventional multi-chip package device of FIG. 2 in a temperature-increasing condition;

FIG. 3b (PRIOR ART) is a schematic view showing the conventional multi-chip package device of FIG. 2 in a temperature-decreasing condition;

FIG. 4a is a partial top view of a multi-chip package device according to the present invention;

FIG. 4b is a cross-sectional view of the multi-chip package device according to the present invention taken along line 4b-4b in FIG. 4a;

FIG. 4c is a top view showing the heat sink in the multi-chip package device according to the present invention;

FIG. 5 is a schematic view showing the heat sink according to the present invention exerted with thermal stresses;

FIGS. 6a and 6b are schematic views showing fabrication processes for the multi-chip package device according to the present invention; and

FIGS. 7a through to 7c are schematic views showing the examples of hollow parts formed in the heat sink according to the present invention.

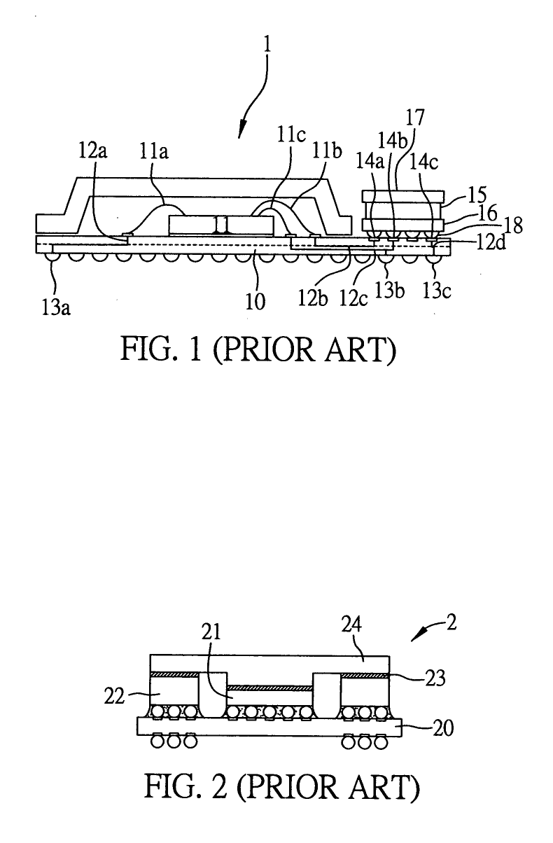

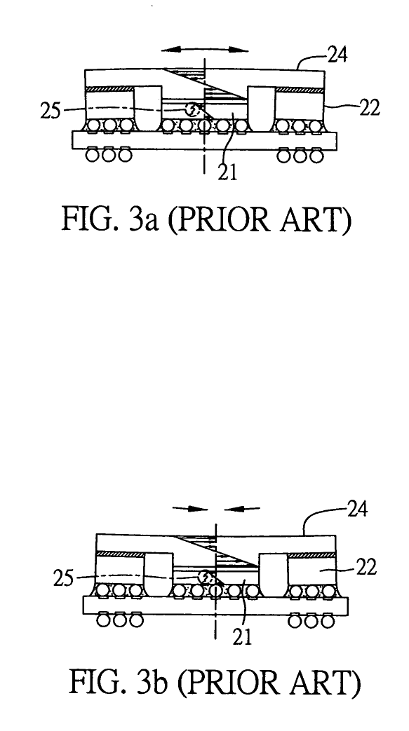

### DETAILED DESCRIPTION OF THE PREFERRED EMBODIMENTS

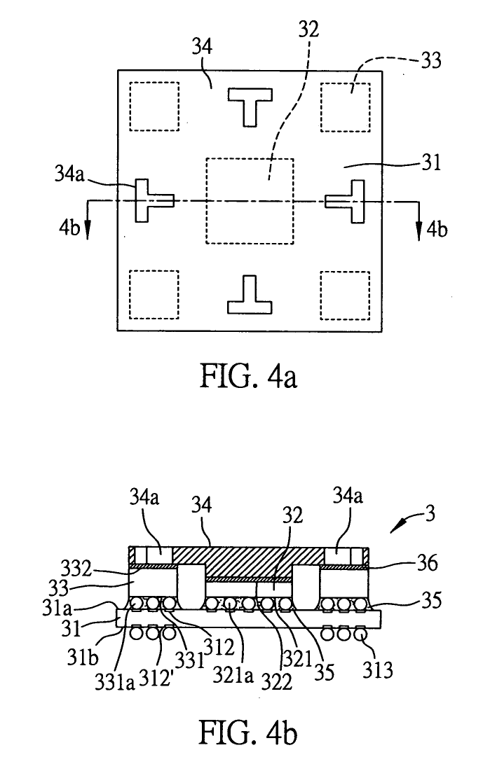

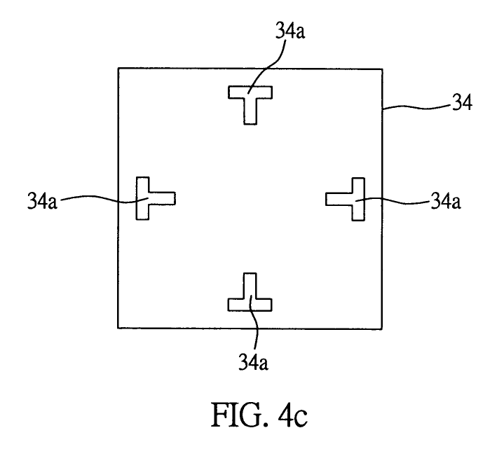

As shown in FIGS. 4a, 4b and 4c, a multi-chip package device 3 proposed by the present invention comprises a chip carrier 31, a first chip 32, a plurality of semiconductor packages 33, and a heat sink 34.

The chip carrier 31 has a first surface 31a and a second surface 31b opposite to the first surface 31a. A plurality of conductive traces (not shown) are formed on the first surface 31a and the second surface 31b respectively, wherein bond pads 312 are formed at terminals of the conductive traces on the first surface 31a, and bond pads 312′ are formed at terminals of the conductive traces on the second surface 31b and bonded with an array of solder balls 313 that mediate electrical connection of the package device 3 with an external device (not shown).

The first chip 32 has an active surface 321 and an inactive surface 322. The first chip 32 is mounted on the chip carrier 31 in a flip-chip manner that, a plurality of bumps 321a formed on the active surface 321 are soldered to the bond pads 312 on the first chip surface 31a of the chip carrier 31, making the first chip 32 electrically connected to the chip carrier 31 via the bumps 321a. The first chip 32 may be disposed at the center of the chip carrier 31. An underfill material 35 is applied between the first chip 32 and the chip carrier 31 to enhance the soldering strength of the bumps 321a. In this embodiment, the package device 3 is a graphic chip package on a graphic adapter, and the first chip 32 is a graphic chip or graphic processing unit.

Each of the semiconductor packages 33 has a lower surface 331 and an upper surface 332. The semiconductor package 33 is mounted on the chip carrier 31 by Surface Mount Technology (SMT) in a manner that, a plurality of bumps 331a formed on the lower surface 331 are soldered to the bond pads 312 on the first surface 31a of the chip carrier 31, making the semiconductor package 33 electrically connected to the chip carrier 31 via the bumps 331a. The semiconductor packages 33 may be situated around the first chip 32 on the chip carrier 31. Similarly, the underfill material 35 is filled between the semiconductor packages 33 and the chip carrier 31 to enhance the soldering strength of the bumps 331a. In this embodiment, the semiconductor package 33 is a TFBGA package of Random Access Memory (RAM) unit. As shown in FIG. 4b, the TFBGA package 33 is slightly thicker than the first chip 32.

The heat sink 34 is mounted on the inactive surface 322 of the first chip 32 and the upper surfaces 332 of the semiconductor packages 33 via an adhesion layer 36 such as an thermally conductive adhesive having excellent heat conduction. The first chip 32 may be attached to a central position of the heat sink 34, while the semiconductor packages 33 may be attached to corner positions of the heat sink 34. As described above that the semiconductor package 33 is slightly thicker than the first chip 32, a portion of the heat sink 34 attached to the first chip 32 is made thicker than that mounted on the semiconductor package 33. A plurality of hollow parts 34a are formed through the heat sink 34 for the purpose of releasing thermal stresses from the beat sink 34. The hollow parts 34a are located at the area of the heat sink 34 free of contact with the first chip 32 and the semiconductor packages 33 and may be symmetrically arranged.

In this embodiment, the hollow parts 34a of the heat sink 34 has a T-shape and situated between the adjacent semiconductor packages 33; in other words, the semiconductor packages 33 are not exposed to the hollow parts 34a. As described above that the portion of the heat sink 34 attached to the first chip 32 is thicker than that mounted on the semiconductor package 33, the thicker portion of the heat sink 34 would be deformed to a greater extent under temperature variations contributes, and thus the hollow parts 34a through the heat sink 34 are required being dimensioned sufficiently e.g. in width to for effectively release thermal stresses from the heat sink 34 where the first chip 32 is attached. On the contrary, if the hollow parts 34a are not properly sized, thermal stresses may concentrate at areas around the hollow parts 34a where the stresses are not successive, thereby leading to abnormal enlargement of the stresses. Therefore, the size of the hollow parts 34a should be adjusted depending on the thickness of the heat sink 34 to achieve effective stress release.

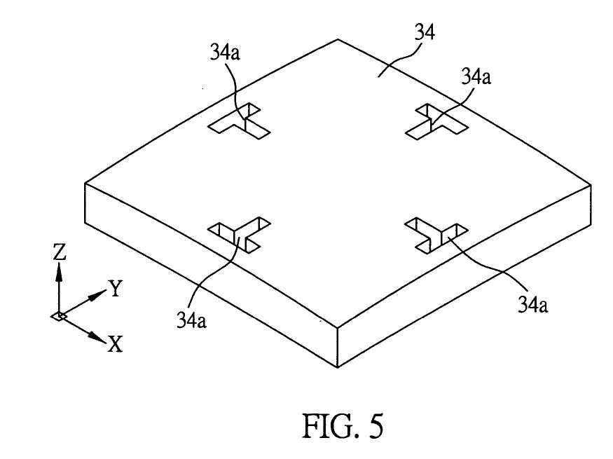

Referring to FIG. 5, since the heat sink 34 usually made of copper has a larger CTE than the first chip 32 and the semiconductor package 33, when the package device 3 is in a temperature-increasing environment, the heat sink 34 expands to a greater extent than the first chip 31 and the package device 32, which may lead to deformation or warpage of the heat sink 34. However, the provision of the hollow parts 34a between the semiconductor packages 33 can alleviate this undesirable deformation or warpage of the heat sink 34 in a manner that the thermal stresses generated from the heat sink 34 can be transmitted the hollow parts 34a and released, thereby significantly reduce the stresses remaining in the heat sink 34. Therefore, as shown in FIG. 5, the heat sink 34 with the stress-releasing hollow parts 34a can maintain intact in structure, thereby preventing delamination of the heat sink 34 from the first chip 32 and the semiconductor package 33.

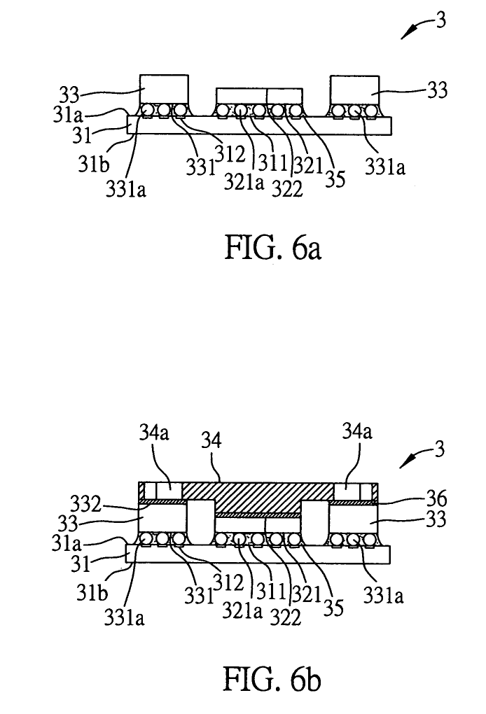

FIGS. 6a and 6b illustrate fabrication processes for the multi-chip package device 3 according to the present invention. Referring to FIG. 6a, the first step is to prepare the chip carrier 31 structured above. The first chip 32 and the semiconductor packages 33 are mounted on the first surface 31a of the chip carrier 31. The first chip 32 is electrically connected in a flip-chip manner to the chip carrier 31 via the bumps 321a bonded to the active surface 321 of the first chip 32. Each of the semiconductor packages 33 is electrically connected to the chip carrier 31 via the bumps 331a formed on the lower surface 331 of the semiconductor package 33. The bonding between the first chip 32 or semiconductor packages 33 and the chip carrier 31 is strengthened by the underfill material 35 filled in-between.

Referring to FIG. 6b, the next step is to mount the heat sink 34 via the adhesion layer 36 on the inactive surface 322 of the first chip 32 and the upper surfaces 332 of the semiconductor packages 33. The heat sink 34 is formed with the plurality of hollow parts 34a for releasing thermal stresses from the heat sink 34, wherein the hollow parts 34a are formed in the area of the heat sink 34 free of contact from the first chip 32 and the semiconductor packages 33.

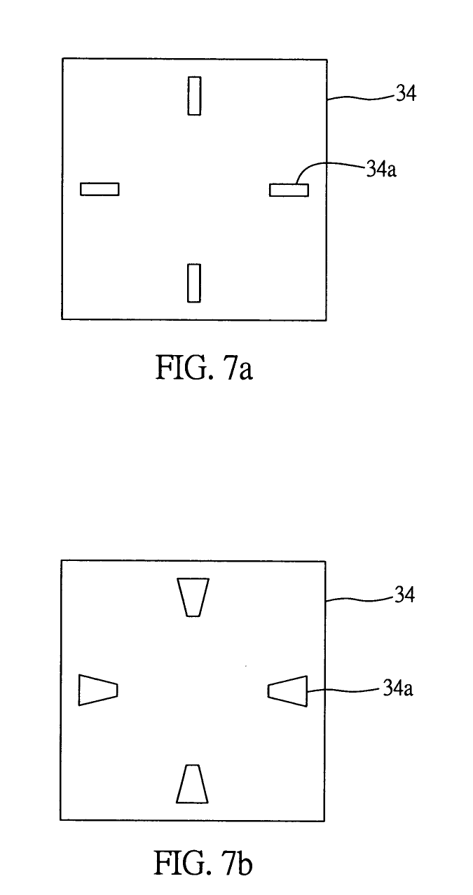

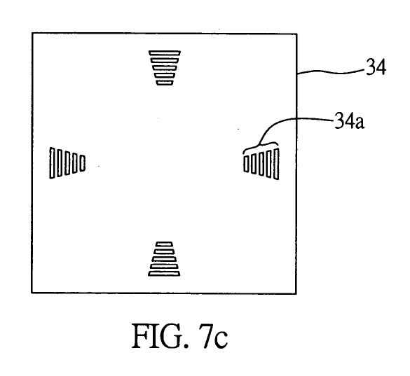

It should be understood that the number and size of the hollow parts 34a in the heat sink 34 can be flexibly adjusted depending on the practical requirement to achieve effective stress release. Further, the hollow parts 34a are not limited to the T-shape configuration; other shapes such as rod-shape, trapezoid shape, and porous shape respectively illustrated in FIGS. 7a, 7b and 7c are suitable for the hollow parts 34a according to the present invention.

In conclusion from the above, in the use of the multi-chip package device according to the present invention, thermal stresses generated from the heat sink especially at areas with the greatest stresses can be released via the hollow parts formed in the heat sink, such that delamination of the heat sink from the chip or semiconductor package mounted in the package device, chip cracking, structural warpage, and deterioration of electrical connection can all be eliminated.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

1. A multi-chip package device with a heat sink, comprising:
a chip carrier for electrically connecting the semiconductor package device to an external device;
at least one first chip mounted on and electrically connected to a surface of the chip carrier;
at least one semiconductor package mounted on and electrically connected to the surface of the chip carrier; and
the heat sink mounted via an adhesion layer on a surface of the first chip and a surface of the semiconductor package that are opposite to surfaces of the first chip and the semiconductor package mounted on the chip carrier, wherein at least one hollow part extending through the heat sink is formed at an area of the heat sink free of contact with the first chip and the semiconductor package to release thermal stresses from the heat sink.

2. The multi-chip package device of claim 1, wherein the semiconductor package is a flip-chip ball grid array package.

3. The multi-chip package device of claim 1, wherein the first chip is a graphic chip.

4. The multi-chip package device of claim 1, wherein the first chip is a graphic processing unit.

5. The multi-chip package device of claim 1, wherein the semiconductor package is a Random Access Memory (RAM) unit.

6. The multi-chip package device of claim 1, wherein the first chip is mounted at the center of the chip carrier, and the semiconductor package is mounted at a position on the chip carrier corresponding to a corner of the heat sink.

7. The multi-chip package device of claim 1, wherein at least one pair of the semiconductor packages are mounted on the chip carrier, and the hollow part of the heat sink is located between the semiconductor packages.

8. The multi-chip package device of claim 1, wherein at least one symmetrical pair of the hollow parts are formed through the heat sink.

9. A fabrication method for a multi-chip package device with a heat sink, the method comprising steps of:
preparing a chip carrier and mounting at least one first chip and at least one semiconductor package on a surface of the chip carrier; and
mounting the heat sink via an adhesion layer on a surface of the first chip and a surface of the semiconductor package that are opposite to surfaces of the first chip and the semiconductor package mounted on the chip carrier, wherein at least one hollow part extending through the heat sink is formed at an area of the heat sink free of contact with the first chip and the semiconductor package to release thermal stress generated from the heat sink.

10. The fabrication method of claim 9, wherein the semiconductor package is a flip-chip ball grid array package.

11. The fabrication method of claim 9, wherein the first chip is a graphic chip.

12. The fabrication method of claim 9, wherein the first chip is a graphic processing unit.

13. The fabrication method of claim 9, wherein the semiconductor package is a Random Access Memory (RAM) unit.

14. The fabrication method of claim 9, wherein the first chip is mounted at the center of the chip carrier, and the semiconductor package is mounted at a position on the chip carrier corresponding to a corner of the heat sink.

15. The fabrication method of claim 9, wherein at least one pair of the semiconductor packages are mounted on the chip carrier, and the hollow part of the heat sink is located between the semiconductor packages.

16. The fabrication method of claim 9, wherein at least one symmetrical pair of the hollow parts are formed through the heat sink.

17. The fabrication method of claim 9, wherein the first chip is mounted on the chip carrier by flip-chip technology.

18. The fabrication method of claim 9, wherein the semiconductor package is mounted on the chip carrier by surface mount technology.
